(19) United States
(12) Patent Application Publication
(10) Pub. No.: US 2024/0266146 A1
(43) Pub. Date: Aug. 8, 2024

(54) PLASMA PROCESSING IMPROVEMENT

(71) Applicant: Applied Materials, Inc., Santa Clara, CA (US)

(72) Inventors: Christopher S. OLSEN, Fremont, CA (US); Rene GEORGE, San Carlos, CA (US); Victor CALDERON, Sunnyvale, CA (US)

(21) Appl. No.: 18/106,981

(22) Filed: Feb. 7, 2023

(51) Int. Cl. H01J 37/32

(52) U.S. Cl. CPC H01J 37/32422; H01J 2237/15; H01J 2237/3323

(57) ABSTRACT

A process chamber is provided including a chamber body disposed around a process volume, the process volume bounded by one or more interior side walls; a substrate support in the process volume; a plasma source disposed over the substrate support, the plasma source having a top and one or more sides disposed around a plasma-generating volume; and a first deflector positioned at least partially in the process volume, the first deflector comprising an annular body having a top, a bottom, one or more outer side surfaces connecting the top with the bottom, and one or more inner side surfaces connecting the top with the bottom. The one or more outer side surfaces of the annular body are spaced apart from the one or more interior side walls of the process volume.

### BACKGROUND

### Field

Embodiments of the present disclosure generally relate to plasma processing equipment and related methods, and more specifically to equipment used to control uniformity of a plasma in a process chamber.

### Description of the Related Art

Plasma processing is used for deposition, etching, resist removal, and other processing of substrates (e.g., semiconductor substrates). Controlling the uniformity of a plasma over a substrate can be challenging. When a plasma has a nonuniform shape over a substrate, the process results (e.g., deposition thickness) can be nonuniform across the substrate. Showerheads and other gas flow devices can be used with the intention of providing a uniform plasma over a substrate, but unfortunately nonuniformities remain in the plasma that is provided above substrates during various processes.

Therefore, there is a need for improved equipment and related methods for providing a more uniform plasma over substrates during plasma processes.

### SUMMARY

Embodiments of the present disclosure generally relate to deflectors used to improve the uniformity of a plasma over a substrate (e.g., a semiconductor substrate) during plasma processes. The deflectors can improve a uniformity of plasma concentration over different portions of the substrate by deflecting plasma species (e.g., ions and radicals) as the plasma species move from the plasma source towards the substrate.

In one embodiment, a process chamber is provided including a chamber body disposed around a process volume, the process volume bounded by one or more interior side walls; a substrate support in the process volume; a plasma source disposed over the substrate support, the plasma source having a top and one or more sides disposed around a plasma-generating volume; and a first deflector positioned at least partially in the process volume, the first deflector comprising an annular body having a top, a bottom, one or more outer side surfaces connecting the top with the bottom, and one or more inner side surfaces connecting the top with the bottom. The one or more outer side surfaces of the annular body are spaced apart from the one or more interior side walls of the process volume.

In another embodiment, a process chamber is provided including a chamber body disposed around a process volume; a substrate support in the process volume; a plasma source disposed over the substrate support, the plasma source having a top and one or more sides disposed around a plasma-generating volume, the plasma-generating volume bounded by one or more interior side walls; and a first deflector positioned at least partially in the plasma-generating volume, the first deflector comprising an annular body having a top, a bottom, one or more outer side surfaces connecting the top with the bottom, and one or more inner side surfaces connecting the top with the bottom. The one or more outer side surfaces of the annular body are spaced apart from the one or more interior side walls of the plasma-generating volume.

In another embodiment, a process chamber is provided including a chamber body disposed around a process volume; a substrate support in the process volume; a plasma source disposed over the substrate support, the plasma source having a top and one or more sides disposed around a plasma-generating volume; and a deflector positioned between the substrate support and the top of the plasma source, the deflector comprising an annular body having a top, a bottom, one or more outer side surfaces connecting the top with the bottom, one or more inner side surfaces connecting the top with the bottom, and a plurality of holes extending through the annular body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a cross-sectional side view of a plasma processing system, according to one embodiment.

FIG. 2A shows a top perspective view of the deflector shown in FIG. 1, according to one embodiment.

FIG. 2B is a partial side cross-sectional view of the annular body taken along section plane 2B of FIG. 2A.

FIG. 2C is a partial side cross-sectional view of an annular body of a deflector, according to another embodiment.

FIG. 2D is a partial side cross-sectional view of an annular body of a deflector, according to another embodiment.

FIG. 3 shows a cross-sectional side view of a plasma processing system, according to one embodiment.

FIG. 4 shows a cross-sectional side view of a plasma processing system, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to deflectors used to improve the uniformity of a plasma over a substrate (e.g., a semiconductor substrate) during plasma processes. The deflectors can convert the geometry of a plasma generated by a plasma source from an irregular geometry to a geometry more closely corresponding to the geometry of the substrate or wafer (e.g., a disc-shaped geometry). The deflectors can improve a uniformity of plasma concentration over different portions of the substrate by deflecting plasma species (e.g., ions and radicals) as the plasma species move from the plasma source towards the substrate. The deflectors can deflect the species away from areas over the substrate that have a higher than average concentration when a deflector is not used. Similarly, the deflectors can deflect the species towards areas over the substrate having a lower than average concentration when a deflector is not used. Overall, using the deflectors described herein improves the uniformity of plasma concentration over a substrate during a plasma process, which improves the uniformity of the plasma process performed on the substrate, such as a plasma deposition, plasma etch, or other plasma process. Used herein plasma concentration refers to the concentration of the different ions, radicals, and other species in a plasma generated in a process chamber.

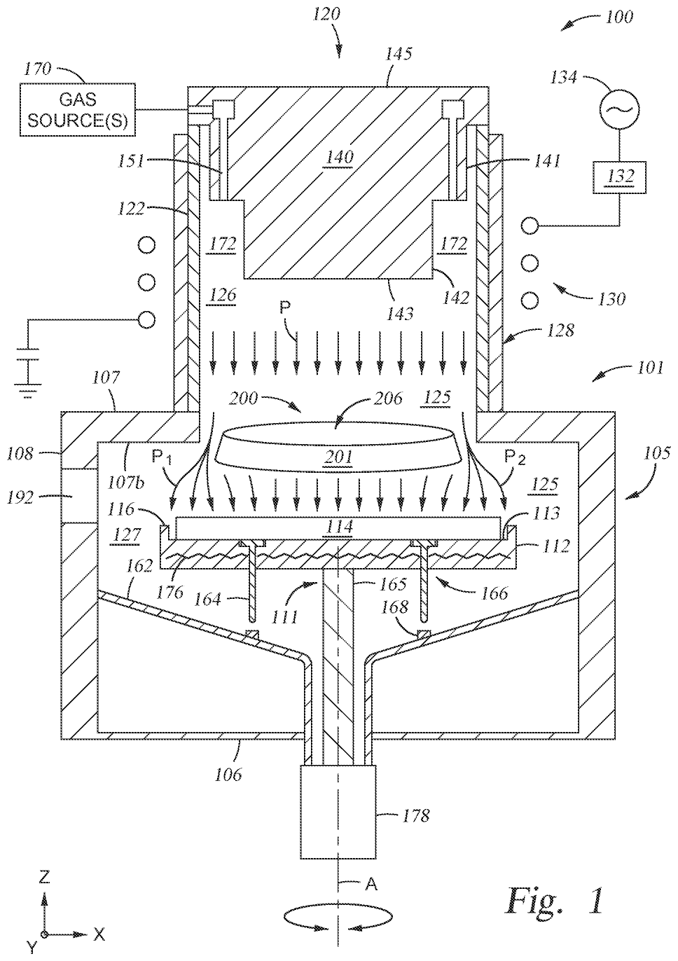

FIG. 1 shows a cross-sectional side view of a plasma processing system 100, according to one embodiment. The plasma processing system 100 includes a process chamber 101. The process chamber 101 includes a chamber body 105 and a plasma source 120 positioned on the chamber body 105. The process chamber 101 includes a substrate support 112 positioned inside the chamber body 105. The plasma processing system 100 further includes one or more gas sources 170. The one or more gas sources 170 can provide one or more gases to the interior of the plasma source 120. The plasma source 120 can generate a plasma P inside the plasma source 120 from the one or more gases provided from the one or more gas sources 170.

The process chamber 101 further includes a deflector 200. The deflector 200 includes an annular body 201. The deflector 200 can deflect plasma species (e.g., ions and radicals) as the plasma species move towards the substrate support 112 to improve the plasma uniformity over the substrate support 112 during a process, which in turn improves the uniformity of the process results (e.g., deposition thickness uniformity) across the substrate. The deflectors described herein (e.g., deflector 200) can be formed of materials that are less likely to cause plasma species recombination, such as sapphire, quartz, fused silica, or borosilicate.

The chamber body 105 includes a bottom 106, a top 107, and one or more side walls 108 connecting the bottom 106 to the top 107. The plasma source 120 can be positioned on the top 107 of the chamber body 105. The chamber body 105 can further include an exhaust port 192 for removing gases and species from an interior volume 125 of the process chamber 101 and to control the pressure in the interior volume 125 during processing. The exhaust port 192 can be coupled to a vacuum pump (not shown).

The process chamber 101 includes a substrate support assembly 111 that includes the substrate support 112. The substrate support 112 includes a substrate supporting surface 113. A substrate 114 can be positioned on the substrate supporting surface 113 of the substrate support 112 during processing. The substrate support assembly 111 further includes an actuator 178 and a shaft 165 coupled between the actuator 178 and the substrate support 112. The actuator 178 is configured to provide rotational movement of the shaft 165 and substrate support 112 about an axis A. The actuator 178 can also be configured to provide for vertical movement of the substrate support 112. For example, in some embodiments a distance between the top surface 113 of the substrate support 112 and the deflector 200 can be adjusted by the actuator 178 by raising or lowering the substrate support 112.

The substrate support assembly 111 assembly further includes lift pins 164 and lift pin holes 166. The lift pin holes 166 extend through the substrate support 112 to the substrate supporting surface 113. The lift pin holes 166 are each sized to accommodate one of the lift pins 164 for lifting of the substrate 114 from the substrate support 112. The lift pins 164 may rest on lift pin stops 168 when the substrate support 112 is lowered from a processing position to a transfer position in which the substrate 114 is elevated above the substrate support 112.

The process chamber 101 includes a window 162 positioned between the substrate support 112 and the bottom 106 of the chamber body 105. The process chamber 101 further includes one or more heat sources 176 in the substrate support 112. The one or more heat sources 176 can provide heat to the substrate 114 during processing of the substrate 114 in the processing chamber 101. Although the one or more heat sources 176 are shown as a resistive heater, in some embodiments other heat sources can be used, such as one or more lamps below the substrate support 112.

The chamber body 105 and the plasma source 120 enclose the interior volume 125. The interior volume 125 can include a processing volume 127 located between the substrate supporting surface 113 and the bottom surface 107b of the top 107 of the chamber body 105. The plasma source 120 can be disposed over the chamber body 105 and around an inner volume 126. The inner volume 126 is also referred to as a plasma-generating volume. The inner volume 126 is a portion of the interior volume 125. A plasma can be generated in the inner volume 126 by the plasma source 120 as described in further detail below. The inner volume 126 extends to the bottom surface 107b of the top 107 of the chamber body.

The process chamber 101 further includes the deflector 200. Although FIG. 1 is shown as a side cross-sectional view with no depth in the Y-direction, the deflector 200 is illustrated as having depth in the Y-direction, so that the ring shape and benefits of the deflector 200 can be more easily described. For example, the plasma P generated by the plasma source 120 can move through a central hollow region 206 of the deflector 200 towards the substrate 114 on the substrate support 112. Portions of the plasma (see e.g., P₁) can flow around the one or more sides of the deflector 200 towards the substrate 114 and the substrate support 112. The deflector 200 can be used to improve the uniformity of the concentration of plasma over the substrate 114 during processing. The deflector 200 has an annular shape. The deflector 200 can be described as having a shape of a frustum or hollow truncated cone. The deflector 200 can be supported in the interior volume 125 using one or more supports (not shown). In some embodiments, the supports can extend from chamber body 105 or from a portion of the plasma source 120. The supports (e.g., rods or brackets) can be formed of materials that are less likely to cause plasma species recombination. The other deflectors described in this disclosure can be supported inside a corresponding process chamber in a similar manner.

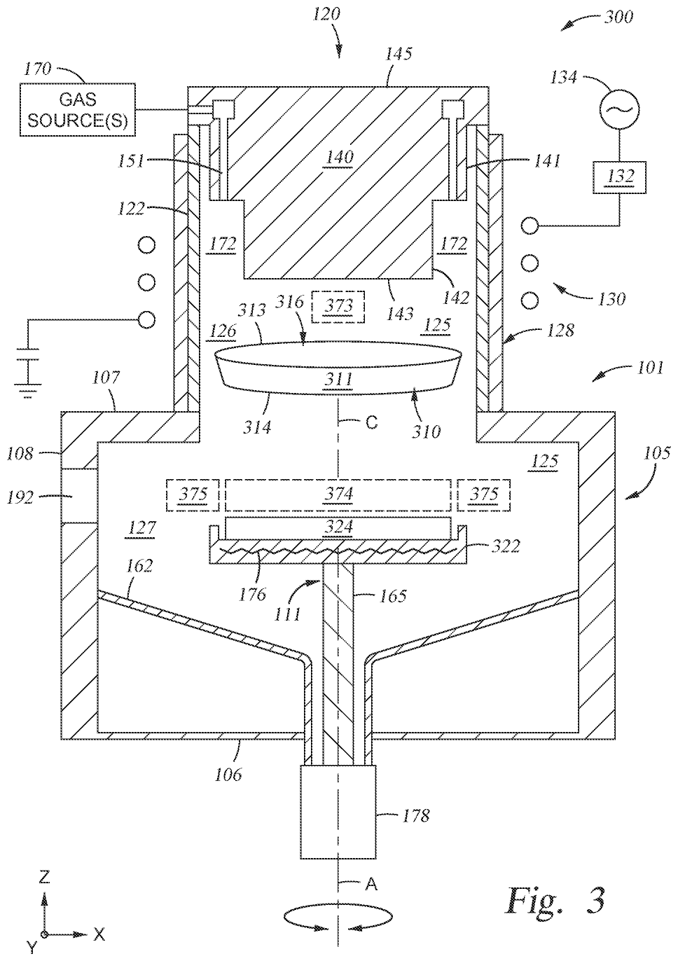

In some embodiments, the central hollow region 206 can span an area in the XY plane that is from about 30% to about 100% of the area of the top surface 113 of the substrate support 112, such as spanning an area that is at least 50% of the area of the top surface 113 of the substrate support 112. In other embodiments, the hollow central portion of the deflector (see e.g., deflector 310 in FIG. 3) can be larger than the top surface of the substrate support.

Although the deflector 200 is shown as being located partially in the processing volume 127 and partially in the inner volume 126, in some embodiments the deflector 200 can be positioned entirely in the processing volume 127 of the chamber body 105 or entirely in the inner volume 126 of the plasma source 120.

Although the geometry of the deflectors described herein are generally described as having circular geometries in the XY plane (i.e., the plane that is parallel to the top surface of the substrate support), this is not meant to be limiting. The deflectors can have other geometries in the XY plane, such as oval, square, rectangular, other polygons, or even irregular shapes. Thus, when a term, such as diameter is used, it is to be understood that one skilled in the art could substitute a corresponding dimension of the deflectors having other shapes in the XY plane.

The plasma source 120 includes a sidewall 122. The plasma source 120 further includes an insert 140. The insert 140 can include a rim 145 on an upper portion of the insert 140. The rim 145 can be positioned on the sidewall 122 of the plasma source 120.

The insert 140 can include one or more gas injection channels 151. One or more gases can be provided from the one or more gas sources 170 to the inner volume 126 of the plasma source 120 through the gas injection channels 151.

The plasma source 120 further includes a plurality of coils 130. In some embodiments, the plasma source can include fewer coils (e.g., one coil) or more coils. The plasma processing system 100 further includes a radio frequency power source 134 and a matching network 132. The RF power source 134 can provide RF power to the plurality of coils 130 through the matching network 132 to induce a magnetic field in inner volume 126 of the plasma source 120 to generate the plasma P from the gases provided from the one more gas sources 170. Although the power source 134 is referred to as an RF power source, in some embodiments other frequencies beside radio frequencies can be used. In some embodiments, the plasma source 120 includes a grounded Faraday shield 128 to reduce capacitive coupling of the induction coils 130 to the plasma.

In some embodiments, the insert 140 can have an irregular shape. For example, the irregular shape of the insert 140 shown in FIG. 1 can be used to create a confinement region 172 for more efficient generation of plasma P. In some embodiments, the confinement region 172 and portions of the inner volume 126 underlying the confinement region 172 can have the highest concentration of plasma in the inner volume 126 when the plasma is generated. As shown, the insert 140 can include a first outer edge 141 and a second outer edge 142. The insert 140 further includes a bottom 143. The outer edges 141, 142 can connect the rim 145 to the bottom 143. The second outer edge 142 can be spaced apart further from the sidewall 122 than the first outer edge 141 is from the sidewall 122. The space between the second outer edge 142 and the sidewall 122 can form the confinement region 172. In some embodiments, the confinement region 172 can have an annular shape with the lower portion of the insert 140 occupying the space inside the annular shape of the confinement region 172.

The portion of the inner volume 126 of the plasma source 120 at radial locations that include the confinement region 172 has a higher height (first height) than the lower height (second height) of the central portion of the inner volume 126 that does not include the radial locations of the confinement region 172. This higher height at the outer radial locations of the confinement region 172 also allows more plasma to be generated at these outer radial locations relative to the central portion of the inner volume 126 that has the lower height. The annular body 201 of the deflector 200 and other deflectors can often be positioned to underlie at least a portion of these outer radial locations of the inner volume 126 that include the confinement region 172 and the portion of the inner volume having a higher height than the central portion of the inner volume 126.

Although the reduced space of the confinement region 172 can help generate plasma P more efficiently, use of the confinement region 172 results in higher concentrations of plasma P in regions of the inner volume 126 underlying the confinement region 172 than in other regions (e.g., a central region underlying the bottom 143 of the insert 140). When a deflector (e.g., deflector 200) or other device to alter the concentration of plasma in a radial direction is not used, this plasma concentration difference in the inner volume 126 of the plasma source 120 can then result in corresponding differences in concentration of plasma P over the substrate 114 in the process volume 127. For example, when a device such as the deflector 200 is not used, regions in the process volume 127 directly underlying the confinement region 172 can have higher concentrations of plasma P than regions overlying a center of the substrate 114 and higher than regions overlying an edge of the substrate 114. These concentration differences in the process volume 127 can then result in process nonuniformities, such as a thicker deposition in a region of the substrate 114 directly underlying the confinement region 172 relative to other portions of the substrate, such as the center and edge regions of the substrate.

Also, the edge of the substrate 114 underlies the top 107 of the chamber body 101, which results in the region overlying the edge of the substrate 114 having a lower plasma concentration. In some embodiments, this location of the edge of the substrate 114 underlying the top 107 of the chamber body 101 can be the largest contributor to plasma non-uniformity (i.e., a larger contributor than the higher plasma concentration in the confinement region 172 relative to other regions). Also, the additional surfaces around the edge of the substrate 114, such as the outer rim 116 of the substrate support 112, the interior sidewalls of the plasma source 120, and the top 107 of the chamber body 101, can cause higher levels of plasma recombination, which can further lower the plasma concentration around the edge of the substrate 114 relative to over other portions of the substrate 114, such as over the center of the substrate 114. As described in further detail below, the deflector 200 can increase the plasma concentration over the edge of the substrate 114 to address the lower plasma concentration around the edge of the substrate 114 due to (1) the location of the edge of the substrate 114 underlying the top 107 of the chamber body, and (2) the additional surfaces located near the edge of the substrate 114 that result in higher levels of plasma recombination.

The insert 140 can be formed of a material that has a low recombination rate for the radicals present in the plasma P formed in the inner volume 126. In some embodiments, the insert 140 can be formed of a dielectric material (e.g., quartz) or a coated metal (e.g., coated aluminum, anodized aluminum oxide). The sidewall 122 can be formed of a dielectric material.

In some embodiments, the insert 140 can be omitted. In one of these embodiments, the inner volume 126 of the plasma source 120 can be a hollow cylindrical volume. Although a hollow cylindrical volume may lack confinement regions, such as the confinement region 172, a hollow cylindrical volume can still generate a plasma that has spatial non-uniformities. Thus, deflectors similar to the deflectors described herein can be used to improve the spatial uniformity of a plasma over the substrate for a plasma generated by a plasma source having a hollow cylindrical inner volume.

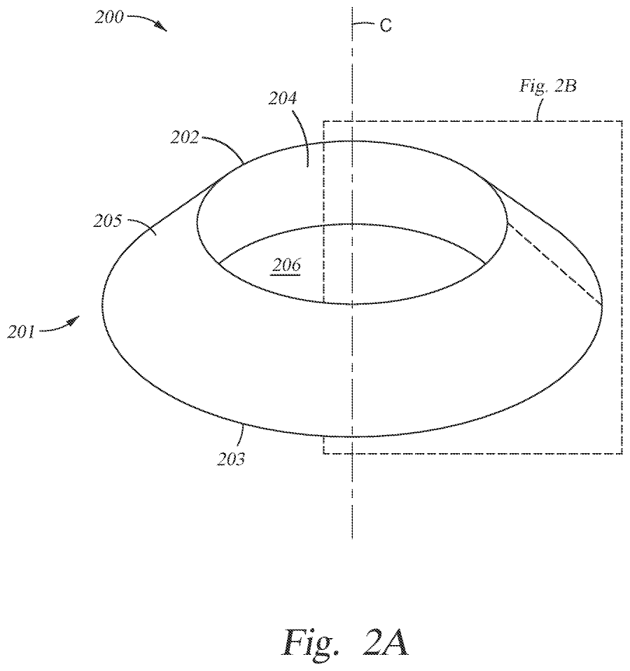

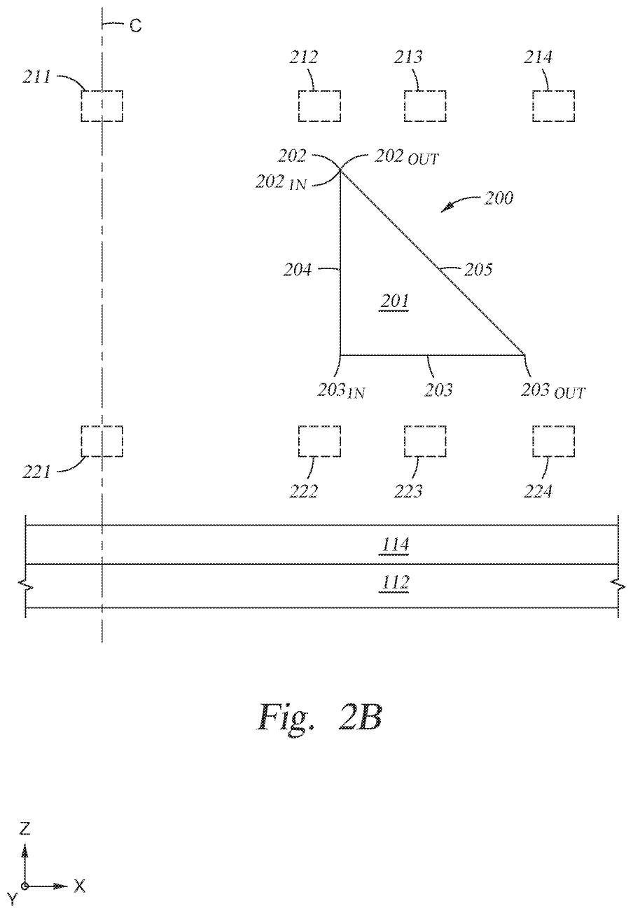

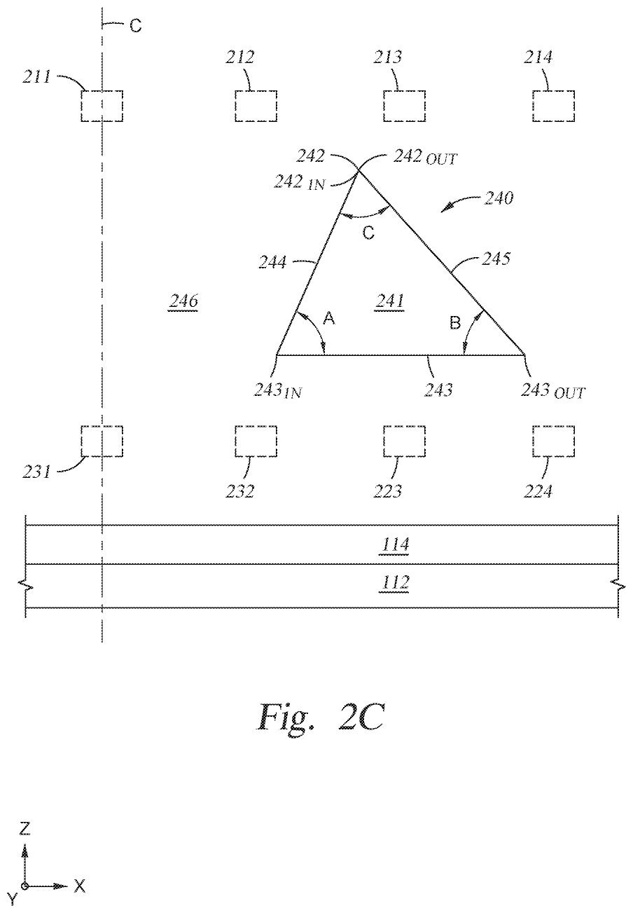

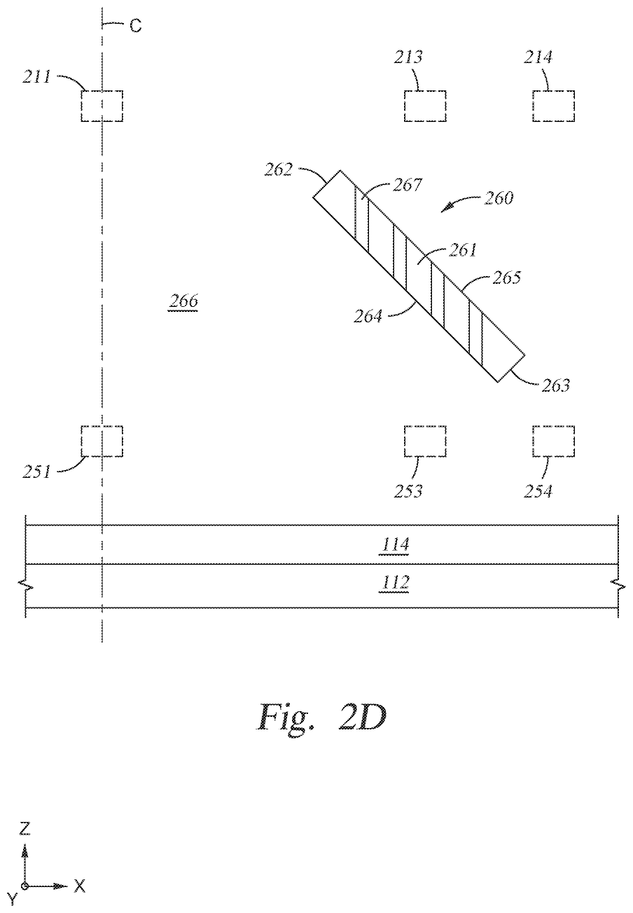

FIG. 2A shows a top perspective view of the deflector 200 shown in FIG. 1, according to one embodiment. The deflector 200 includes the annular body 201. The annular body 201 of the deflector 200 includes a top 202, a bottom 203, an inner side surface 204, and an outer side surface 205. The side surfaces 204, 205 can connect the top 202 with the bottom 203. The annular body 201 can be disposed around the central hollow region 206.

The outer side surfaces 205 of the annular body 201 are spaced apart from the interior sidewalls that surround the process volume 127, so that plasma can flow outward of the outer side surfaces 205 of the annular body 201 when the plasma flows from the plasma-generating volume 126 towards the substrate support 112. The interior sidewalls that surround process volume 127 can include the interior side surfaces of the chamber body 105, such as the interior side surfaces of the side walls 108 and the top 107 as well as interior side surfaces of components (not shown) that can be positioned against the interior surfaces of the chamber body 105, such as liners. Allowing the plasma to flow around the outer side surfaces 205 of the deflector 200 allows plasma to be deflected towards outer regions of the substrate 114, such as the edge of the substrate 114 as the plasma flows towards the substrate support 112 from the plasma-generating volume 126.

In each of the embodiments of the deflectors described herein, the outer side surfaces of the given deflector can be spaced apart from the interior surfaces that surround the process volume 127 and/or the plasma-generating volume 126, so that plasma can flow around the outer side surfaces of these deflectors. However, in some embodiments, a deflector can have outer side surfaces contacting an interior sidewall of the process volume and/or plasma-generating volume, which can be useful when the deflector is used to deflect plasma inwardly, such as when a deflector has a larger diameter than the substrate being processed.

With reference to FIG. 1 and FIG. 2A, the slope of the side surfaces 204, 205 as well as the distance between the top 202 and the bottom 203 can be used to control the deflection of the plasma P as the plasma P moves past the deflector 200 and towards the substrate support 112 during processing. Additionally, the vertical position of the deflector in the interior volume 125 can be adjusted to modify the distribution of plasma P over the substrate support 112.

FIG. 2A also shows a central vertical axis C passing through a center of the hollow central region 206. Although not shown in FIG. 1, the central vertical axis C can also pass through a center of the top surface of the substrate 114 and the substrate support 112 in their respective XY planes. Additionally, the central vertical axis C can pass vertically through a center of the insert 140. Used herein, inner and inwardly refer to location(s) closer to the central vertical axis C in an XY plane relative to the distances of one or more other locations to the central vertical axis C in their respective XY planes. Similarly, outer and outwardly refer to location(s) further from the central vertical axis C in an XY plane relative to the distances of one or more other locations to the central vertical axis C in their respective XY planes.

FIG. 2B is a partial side cross-sectional view of the annular body 201 taken along section plane 2B of FIG. 2A. The cross-section of the annular body 201 is shown as a right triangle, but can alternatively have a variety of shapes, such as the examples shown in FIGS. 2C and 2D as well as other shapes. Also, although the side surfaces 204, 205 and the bottom 203 are shown as being straight, these surfaces can also be curved or partially curved in some embodiments. The top 202 of the annular body 201 is illustrated as coming to a point, so an inner edge 202_{IN} and an outer edge 202_{OUT} of the top 202 are shown as being located at a same position in FIG. 2B. Although the top 202 is illustrated as coming to a point, there would always be at least some difference between the inner edge 202_{IN} and the outer edge 202_{OUT} of the top 202, such as a few mm. The bottom 203 includes an outer edge 203_{OUT} and an inner edge 203_{IN}. In some embodiments, the top 202 may have a shape other than a point, such as curved surface.

The outer edge 203_{OUT} of the bottom 203 is located outwardly relative to the outer edge 202_{OUT} of the top 202, which causes an increase in a concentration of plasma in regions below the deflector 200 and outward of outer edge 203_{OUT} of the bottom 203 as the plasma P moves towards the substrate support 112. For example, a concentration of plasma P in a region 224 that is below and slightly outward (e.g., 1-5 mm) of the outer edge 203_{OUT} of the bottom 203 is higher than a region 214 that is above the deflector 200 and directly overlies the region 224. Referring to FIG. 1, the processing volume 127 is larger in a radial direction from the vertical central axis C (see FIG. 2B) and portions of the top surface of the substrate 114 do not directly underlie a portion of the narrower inner volume 126 of the plasma source 120. Used herein, radial generally refers to distance from the central vertical axis C or another vertical axis.

Without the use of a device, such as the deflector 200, these outer regions of the process volume 127 can have a lower plasma concentration relative to other inner regions, such as regions underlying the confinement region 172. The slope of the outer side surface 205 away from the vertical central axis C in the downward direction can increase the plasma concentration in regions of the process volume 127 that do not directly underlie a portion of the inner volume 126 of the plasma source 120, such as regions overlying edge regions of the substrate 114, which can improve plasma concentration uniformity.

Conversely, the deflector 200 reduces a concentration of plasma in regions directly below the deflector 200 compared to corresponding regions directly overlying the deflector 200. For example, a region 223 that directly underlies a central portion of the annular body 201 has a lower concentration of plasma compared to a region 213 that is above the deflector 200 and directly overlies the region 223. The region 223 has a lower plasma concentration than the overlying region 213 because the deflector 200 deflects some of the plasma inwardly and outwardly away from regions that directly underlie the annular body 201, such as the region 223. Referring to FIG. 1 and FIG. 2B, region 213 directly underlies the confinement region 172 which generates a higher concentration of plasma, and thus region 213 has a higher plasma concentration than regions at a same vertical location that do not underlie the confinement region 172, such as regions 211, 214. Thus, the plasma concentration reduction in region 223 relative to region 213 can improve the uniformity of the plasma concentration over the substrate 114.

In some embodiments, the deflector 200 can also increase a concentration of plasma in regions located inward of the inner edge 203_{IN} of the bottom 203 and below the deflector 200 compared to corresponding directly overlying regions above the deflector 200. For example, in some embodiments, a concentration of plasma in a region 222 that is below and slightly inward (e.g., 1-5 mm) of the inner edge 203_{IN} of the bottom 203 can be higher than a region 212 that is above the deflector 200 and directly overlies the region 222. In some embodiments, the inner side surface 204 can be sloped towards the central axis C as the inner side surface 204 extends from the top 202 towards the bottom 203, which can increase the amount which the concentration of plasma increases in regions below and slightly inward of the bottom inner edge 203_{IN}, such as the region 222, compared to corresponding regions directly overlying those regions, such as the region 212.

The deflector 200 can also increase a concentration of plasma in a central region 221 below the deflector 200 that is aligned with the central axis C compared to a corresponding region 211 directly overlying the region 221 that is above the deflector 200. This is because some radicals that would otherwise drift radially outward away from the central axis C are prevented from drifting outward directly by the annular body 201 or indirectly by another plasma species that is redirected towards the central axis C by the annular body 201. Due to the slope of the outer side surface 205 and the vertical orientation of the inner side surface 204, in some embodiments, the deflector 200 may not significantly change the plasma concentration in the regions 221, 222 relative to the directly overlying regions 211, 212, and the deflector 200 has a much more substantial effect on the plasma concentration changes between the regions 223, 224 relative to the directly overlying regions 213, 214. Overall, the deflector 200 improves the uniformity of the plasma concentration over the substrate 114 by decreasing the plasma concentration in regions directly underlying the deflector 200 (e.g., region 223) and increasing the plasma concentration in other regions (e.g., region 224).

FIG. 2C is a partial side cross-sectional view of an annular body 241 of a deflector 240, according to another embodiment. The deflector 240 has an annular shape and is generally similar to the deflector 200 described above, but the deflector 240 has a different size and shape than the deflector 200. The view in FIG. 2C is taken from a plane going through the annular body 241 of the deflector 240 that is substantially equivalent to the location of the section plane 2B going through the annular body 201 of the deflector 200 shown in FIG. 2A. The annular body 241 of the deflector 240 includes a top 242, a bottom 243, an inner side surface 244, and an outer side surface 245. The side surfaces 244, 245 can connect the top 242 with the bottom 243. The annular body 241 can be disposed around a central hollow region 246.

The outer side surface 245 is the same as the outer side surface 205 described above. Thus, the increase in concentration of plasma in the region 224 relative to the concentration of plasma in the region 214 is similar the increase described above for regions 214, 224 in reference to FIG. 2B. Additionally, the reduction of the concentration of plasma in the region 223 relative to the concentration of plasma in the region 213 is similar the reduction described above for regions 213, 223 in reference to FIG. 2B.

In FIG. 2B, the inner side surface 204 is vertical. In FIG. 2C, the inner side surface 244 is sloped towards the central vertical axis C as the inner side surface 244 extends from the top 242 towards the bottom 243, which causes more species in the plasma to move towards regions 231, 232 compared to the corresponding regions 221, 222 described above in reference to FIG. 2B. In some embodiments, increasing the plasma concentration in central regions, such as regions 231, 232 relative to overlying regions 211, 212 can be beneficial in improving the plasma uniformity over the substrate 114.

The deflector 240 includes an inner angle A between the bottom 243 and the inner side surface 244. The deflector 240 includes an outer angle B between the bottom 243 and the outer side surface 245. The deflector 240 includes an upper angle C between the inner side surface 244 and the outer side surface 245. In some embodiments, the upper angle C can be less than 60 degrees, such as less than 45 degrees, such as less than 20 degrees. In some embodiments, lower values (e.g., less than 45 degrees or less than 20 degrees) for the upper angle C can be better for guiding the plasma species inside the process chamber 101.

Having a lower value for the angle C is related the steepness of the side surfaces 244, 245. In some embodiments, a steeper side surface can result in a more uniform distribution of plasma below the deflector. The steepness of a side surface can also be described relative to a horizontal line extending through the top of the side surface. For example, side surface 204 from FIG. 2B can be described as having a 90 degree angle relative to a horizontal line extending through the top of the side surface 204 at the inner edge 202_{IN} of the top 202. Similarly, side surface 205 from FIG. 2B can be described as having a 45 degree angle relative to a horizontal line extending through the top of the side surface 205 at the outer edge 202_{OUT} of the top 202. Describing the steepness of the side surfaces relative to a horizontal line instead of the upper angle C as done for FIG. 2C can be useful for embodiments of deflectors having cross-sectional geometries other than triangular. In some embodiments, it can be beneficial for plasma uniformity to use a deflector having one or more side surfaces in which an angle between the exterior of the side surface and a horizontal line extending through the top of that side surface is greater than 45 degrees, greater than 60 degrees, or greater than 80 degrees.

The angles A and B can be adjusted to modify the proportion of plasma that is deflected towards inner regions (e.g., region 231) relative to outer regions (e.g., region 224). Furthermore, the size of the angle can be used to control the amount of deflection in a horizontal direction. For example, a lower inner angle A may increase the plasma concentration in the central region 231 compared to the corresponding region 221 in FIG. 2B because the right angle and vertical inner side surface 204 (FIG. 2B) caused less deflection towards the central axis C than the deflection towards the central axis C caused by the inner side surface 244 in FIG. 2C. Furthermore, the location of the top 242 in the XY plane (i.e., the radial distance from the central axis C) can affect the proportions of plasma deflected inwardly versus outwardly. Additionally, the distance between the bottom 243 and the top surface of the substrate support 112 can be adjusted to modify the time plasma species have to travel after being deflected by the deflector 240. For example, a greater distance between the bottom of the deflector and the top surface of the substrate support would allow more time for a plasma particle to travel, which can enable more species to reach a central region over the substrate support, such as region 231 compared to a shorter distance between the bottom of the deflector and the top surface of the substrate support 112.

FIG. 2D is a partial side cross-sectional view of an annular body 261 of a deflector 260, according to another embodiment. The deflector 260 has an annular shape and is generally similar to the deflector 200 described above except that the deflector 260 has a different size and shape, and the deflector 260 includes a plurality of holes 267 through the annular body 261. The view in FIG. 2D is taken from a plane going through the annular body 261 of the deflector 260 that is substantially equivalent to the location of the section plane 2B going through the annular body 201 of the deflector 200 shown in FIG. 2A. The annular body 261 of the deflector 260 includes a top 262, a bottom 263, an inner side surface 264, and an outer side surface 265. The side surfaces 264, 265 can connect the top 262 with the bottom 263. The annular body 261 can be disposed around a central hollow region 266.

The annular body 261 of the deflector 260 includes two features to prevent the regions directly underlying the annular body 261 from having a plasma concentration that is below other regions between the substrate 114 and the deflector 260. First, the holes 267 allow some plasma species to travel through the holes towards regions directly underlying the annular body 261, such as the region 253. In some embodiments, the holes 267 can be included around the entire annular body 261. Although FIG. 2D shows four holes 267 arranged in a column, this is for ease of illustration and the holes 267 can be positioned in a variety of arrangements. Although four holes 267 are shown, there can be substantially more holes in a given cross-section. Some embodiments of the deflector may include hundreds or thousands of holes, such as the holes 267.

Each of the other embodiments of deflectors (e.g., deflectors 200, 240, 310, and 410) described herein can also be modified to include holes, such as the holes 267. For example, with reference to FIG. 2C, the deflector 240 can be modified to include holes from either or both of the side surfaces 244, 245 to the bottom 243 and/or from one of the side surfaces 244, 245 to the other side surface 244, 245. In some of these embodiments, the holes have a vertical orientation. In other embodiments, the holes can have a sloped orientation, so that the entrance of each hole can have a different position in an XY plane than the exit that the hole has in a corresponding XY plane. Furthermore, in some embodiments, there can more than one type of hole through the deflector, such as holes having different sizes, different slopes, and/or holes extending through different surfaces.

Second, the inner side surface 264 is sloped outwardly away from the central axis as the inner side surface 264 extends from the top 262 to the bottom 263. This outward slope of the inner side surface 264 allows more plasma species to reach regions directly underlying the deflector 260 than if the inner side surface had another slope, such as the vertical slope of inner side surface 204 (see FIG. 2B) or the inward slope of the inner side surface 244 (see FIG. 2C).

The slope of the outer side surface 265 can increase the plasma concentration of regions located below and outward of the bottom 263 of the deflector 260, such as the region 254, relative to directly overlying regions above the deflector 260, such as region 214. The deflector 260 may have less of an effect on plasma concentrations located inwardly relative to the annular body 261. For example, the region 251 may have a same or substantially similar plasma concentration as the region 211.

FIG. 3 shows a cross-sectional side view of a plasma processing system 300, according to one embodiment. The plasma processing system 300 is similar to the plasma processing system 100 described above except that the plasma processing system 300 includes a deflector 310 instead of the deflector 200, and the plasma processing system 300 includes a smaller substrate support 322 and corresponding substrate 324. The deflector 310 is positioned in the inner volume 126 of the plasma source 120. FIG. 3 shows a portion of central vertical axis C that is the same as the central vertical axis C described above. For example, the central vertical axis C extends through a center of the substrate support 322, substrate 324, deflector 310, and insert 140. Only a portion of the vertical axis C is shown in order to not clutter the drawing. Although FIG. 3 is shown as a side cross-sectional view with no depth in the Y-direction, the deflector 310 is illustrated as having depth in the Y-direction, so that the ring shape of the deflector 310 and benefits of the deflector 310 can be more easily described.

The deflector 310 includes an annular body 311 disposed around a central hollow region 316. The bottom 314 of the deflector 310 has an internal diameter that is larger than the diameter of the substrate 324 and larger than the diameter of the substrate supporting surface of the substrate support 322. The top 313 of the deflector 310 has a larger diameter in an XY plane than the bottom 314 of the deflector 310 has in an XY plane, and the inner side surface of the annular body 311 is sloped towards the central vertical axis C as the inner side surface extends from the top 313 to the bottom 314 of the annular body 311, which enables the deflector 310 to function as funnel. For example, the deflector 310 can funnel plasma species coming from the confinement region 172 towards a central region 374 overlying the substrate 324. The confinement region 172 of the inner volume 126 of the plasma source 120 has a higher plasma concentration than other regions, such as a central region 373 overlying the deflector 310. Thus, the funneling can cause more plasma species to move towards central regions over the substrate support 322, which results in a more uniform plasma concentration over the substrate 324, such as the central region 374 in the processing volume 127 of the chamber body 105. The funneling can also reduce an amount of plasma moving towards regions not overlying the substrate 324, such as the regions 375 in the processing volume 127. Some of the plasma species in regions not overlying the substrate 324 may also be exhausted before interacting with the substrate 324. Therefore, funneling more species to locations overlying the substrate 324 by using the deflector 310 can improve the efficiency of the process being performed since less plasma species are exhausted without interacting with the substrate.

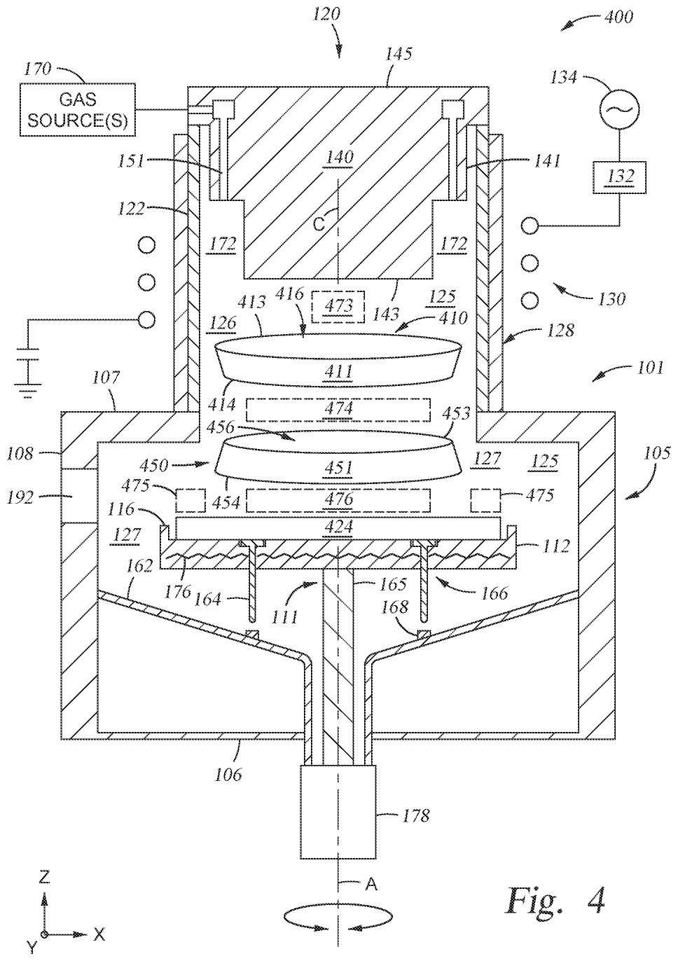

FIG. 4 shows a cross-sectional side view of a plasma processing system 400, according to one embodiment. The plasma processing system 400 is similar to the plasma processing system 100 described above except that the plasma processing system 400 includes a first deflector 410 and a second deflector 450 instead of the deflector 200. A different substrate 424 is also positioned on the substrate support 112. The deflector 410 is positioned in the inner volume 126 of the plasma source 120. The deflector 450 is positioned in the processing volume 127 of the chamber body 105. FIG. 4 shows a portion of central vertical axis C that is the same as the central vertical axis C described above. For example, the central vertical axis C extends through a center of the substrate support 112, substrate 424, first deflector 410, second deflector 450, and insert 140. Only a portion of the vertical axis C is shown in order to not clutter the drawing. Although FIG. 4 is shown as a side cross-sectional view with no depth in the Y-direction, the deflector 410 is illustrated as having depth in the Y-direction, so that the ring shape of the deflector 410 and benefits of the deflector 410 can be more easily described.

The first deflector 410 includes an annular body 411 disposed around a central hollow region 416. The top 413 of the first deflector 410 has a larger internal diameter in an XY plane than the internal diameter of the bottom 414 of the first deflector 410 in an XY plane, and the inner side surface of the annular body 411 is sloped towards the central vertical axis C as the inner side surface extends from the top 413 to the bottom 414 of the annular body 411, which enables the first deflector 410 to function as funnel. For example, the first deflector 410 can funnel plasma species coming from the confinement region 172 towards a central region 474 below the first deflector 410 and overlying the second deflector 450. The confinement region 172 of the inner volume 126 of the plasma source 120 has a higher plasma concentration than other regions, such as a central region 473 overlying the first deflector 410. Thus, the funneling can cause more plasma species to move towards central regions (e.g., region 475) over the second deflector 450 to make the plasma have a more spatially uniform concentration as the plasma moves towards the second deflector 450.

The second deflector 450 includes an annular body 451 disposed around a central hollow region 456. The bottom 454 of the second deflector 450 has a larger internal diameter in an XY plane than the internal diameter of the top 453 of the second deflector 450 in an XY plane, and the inner side surface of the annular body 451 is sloped away from the central vertical axis C as the inner side surface extends from the top 453 to the bottom 454 of the annular body 451, which allows the second deflector to disperse the plasma species over a larger area. For example, plasma species that enter the central hollow region 456 inside the annular body 451 can spread out in a radial direction as the plasma species pass through the central hollow region 456. Furthermore, some plasma species that move downward at a radial direction beyond the outer edge of the top 453 of the second deflector 450 are guided outward by the outer side surface of the annular body 451. Guiding plasma species outward can cause more plasma species to reach regions over the substrate 424 and underlying the top 107 of the chamber body 105, such as regions 475. Without use of a device, such as the deflector 450, regions underlying the top 107 of the chamber body 105 (e.g., regions 475) can have lower plasma concentrations than regions directly underlying the inner volume 126 of the plasma source 120. Thus, the dispersal of plasma species by the deflector 450 in an outward direction can improve the uniformity of plasma concentration over the entire substrate, so that the outer regions 475 can have a same or substantially the same plasma concentration as a central region, such as the central region 476.

In some embodiments, two deflectors (e.g., deflectors 410, 450) can be more effective than one deflector for providing a more uniform plasma over the surface of a substrate, which can produce more uniform process results (e.g., more uniform deposition thickness).

Overall, the deflectors described herein can improve the uniformity of plasma concentration over the surface of substrate during a variety of plasma processes (e.g., deposition, etch, cleaning, another processes). This improvement in plasma uniformity is obtained because the deflectors described herein receive a spatially nonuniform plasma from the plasma source and then (1) guide more plasma species to radial locations overlying the substrate that would otherwise have lower than average plasma concentrations and (2) deflect plasma species away from radial locations overlying the substrate that would otherwise have higher than average plasma concentrations. The solutions provided by this disclosure using deflectors is also an improvement over using devices configured to disperse plasma and gases over an area, such as showerheads or grids, because using these other devices results in an unsatisfactory high level of plasma recombination when the plasma species contact the surfaces of these other devices.

While the foregoing is directed to embodiments of the present disclosure, other and further embodiments of the disclosure may be devised without departing from the basic scope thereof.

What is claimed is:

1. A process chamber, suitable for use in semiconductor manufacturing, comprising:
a chamber body disposed around a process volume, the process volume bounded by one or more interior side walls;
a substrate support in the process volume;
a plasma source disposed over the substrate support, the plasma source having a top and one or more sides disposed around a plasma-generating volume; and
a first deflector positioned at least partially in the process volume, the first deflector comprising an annular body having a top, a bottom, one or more outer side surfaces connecting the top with the bottom, and one or more inner side surfaces connecting the top with the bottom, wherein the one or more outer side surfaces of the annular body are spaced apart from the one or more interior side walls of the process volume.

2. The process chamber of claim 1, wherein an inner edge of the bottom of the annular body is located inwardly relative to an inner edge of the top of the annular body.

3. The process chamber of claim 1, wherein an outer edge of the bottom of the annular body is located outwardly relative to an outer edge of the top of the annular body.

4. The process chamber of claim 1, wherein an angle between a first side surface of the one or more outer side surfaces and a horizontal line extending through the top of the first side surface is greater than 60 degrees.

5. The process chamber of claim 1, wherein
the one or more outer side surfaces includes a first side surface and a second surface,
the first side surface and the second side surface each extend to the top of the annular body, and
an angle between the first side surface and the second side surface is less than 20 degrees.

6. The process chamber of claim 1, wherein the annular body is located partially in the plasma-generating volume.

7. The process chamber of claim 1, wherein
the plasma-generating volume has a height that varies with a distance from a central vertical axis extending through a center of the plasma-generating volume,
an outer portion of the plasma-generating volume has a first height,
a central portion of the plasma-generating volume has a second height,
the first height is greater than the second height, and
the annular body underlies the outer portion.

8. The process chamber of claim 1, wherein the annular body underlies a portion of the plasma-generating volume configured to generate a highest concentration of plasma.

9. The process chamber of claim 1, wherein the annular body includes a plurality of holes extending through the annular body.

10. The process chamber of claim 1, wherein the annular body surrounds an area in a horizontal plane that is at least 50% of a total area of a substrate supporting surface of the substrate support.

11. The process chamber of claim 1, further comprising a second deflector positioned over the first deflector, the second deflector comprising an annular body having a top, a bottom, one or more outer side surfaces connecting the top with the bottom, and one or more inner side surfaces connecting the top with the bottom.

12. The process chamber of claim 11, wherein an outer edge of the bottom of the annular body of the second deflector is located inwardly relative to an outer edge of the top of the annular body of the second deflector.

13. A process chamber suitable for use in semiconductor manufacturing, comprising:
a chamber body disposed around a process volume;
a substrate support in the process volume;
a plasma source disposed over the substrate support, the plasma source having a top and one or more sides disposed around a plasma-generating volume, the plasma-generating volume bounded by one or more interior side walls; and
a first deflector positioned at least partially in the plasma-generating volume, the first deflector comprising an annular body having a top, a bottom, one or more outer side surfaces connecting the top with the bottom, and one or more inner side surfaces connecting the top with the bottom, wherein the one or more outer side surfaces of the annular body are spaced apart from the one or more interior side walls of the plasma-generating volume.

14. The process chamber of claim 13, wherein an inner edge of the bottom of the annular body is located inwardly relative to an inner edge of the top of the annular body.

15. The process chamber of claim 14, wherein an outer edge of the bottom of the annular body is located outwardly relative to an outer edge of the top of the annular body.

16. The process chamber of claim 13, wherein the annular body underlies a portion of the plasma-generating volume configured to generate a highest concentration of plasma.

17. The process chamber of claim 13, wherein the annular body includes a plurality of holes extending through the annular body.

18. The process chamber of claim 13, wherein the annular body surrounds an area in a horizontal plane that is at least 50% of a total area of a substrate supporting surface of the substrate support.

19. A process chamber, suitable for use in semiconductor manufacturing, comprising:
a chamber body disposed around a process volume;
a substrate support in the process volume;
a plasma source disposed over the substrate support, the plasma source having a top and one or more sides disposed around a plasma-generating volume; and
a deflector positioned between the substrate support and the top of the plasma source, the deflector comprising an annular body having a top, a bottom, one or more outer side surfaces connecting the top with the bottom, one or more inner side surfaces connecting the top with the bottom, and a plurality of holes extending through the annular body.

20. The process chamber of claim 19, wherein the plurality of holes underlie a portion of the plasma-generating volume configured to generate a highest concentration of plasma.
